(19) United States
(12) Patent Application Publication
(10) Pub. No.: US 2021/0212192 A1
(43) Pub. Date: Jul. 8, 2021

(54) CIRCUIT DEVICE

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventors: Shigeki Yamane, Yokkaichi-shi, Mie (JP); Toshiyuki Tsuchida, Yokkaichi-shi, Mie (JP)

(21) Appl. No.: 17/057,182

(22) PCT Filed: May 17, 2019
(86) PCT No.: PCT/JP2019/019613

§ 371 Date: Nov. 20, 2020

(30) Foreign Application Priority Data
May 22, 2018 (JP) 2018-097871

(51) Int. Cl. H05K 1/02; H01F 27/02; H05K 1/18

(52) U.S. Cl. CPC H05K 1/021; H01F 2027/065; H05K 1/181; H01F 27/025

(57) ABSTRACT

A circuit device 1 includes a circuit board, an inductor mounted on the circuit board, and a heat dissipation member to which the circuit board and the inductor are assembled. The inductor includes a case main body, and mounting pieces extending from the case main body in parallel with the circuit board. A heat dissipation member includes a main plate portion disposed along a heat dissipation surface on the opposite side of a mounting surface on which the inductor is mounted in the circuit board, and support post portions extending from the main plate portion and penetrating the circuit board and the mounting pieces . The circuit board and the mounting pieces are fixed to the support post portions by an adhesive.

### CROSS-REFERENCE TO RELATED APPLICATIONS

This application is the U.S. national stage of PCT/JP2019/019613 filed on May 17, 2019, which claims priority of Japanese Patent Application No. JP 2018-097871 filed on May 22, 2018, the contents of which are incorporated herein.

### TECHNICAL FIELD

The technique disclosed in the present specification relates to a circuit device.

### BACKGROUND

Conventionally, a circuit device including a circuit board and electronic components mounted on the circuit board is known for letting electricity flow and disconnecting the flow of electricity to in-vehicle electrical components.

In such a circuit device, some electronic components mounted on the circuit board are relatively large, such as inductors. Large electronic components are mechanically fixed on a circuit board by, for example, fastening them with screws because there is a possibility that a crack is generated in solder due to vibration or the like when the vehicle moves, if their terminals are connected to a conductive circuit on the circuit board only by soldering (see JP 2004-253508A).

In the above configuration, a relatively wide space for the task of fastening screws is required around the fastening position of the screws for fixing the electronic components on the circuit board, and a conductor circuit and other electronic components cannot be arranged in that space. Accordingly, there is a limit to how much the density of the circuit board can be increased.

### SUMMARY

A circuit device disclosed in the present specification includes a circuit board, one electronic component mounted on the circuit board, and an assembly member to which the circuit board and the one electronic component are assembled, wherein the one electronic component includes a main body and a mounting piece extending from the main body in parallel with the circuit board, the assembly member includes a base portion disposed along the circuit board, and a support post portion extending from the base portion and penetrating the circuit board and the mounting piece, and the circuit board is fixed to the support post portion, and the mounting piece is fixed to the support post portion, by a fixing member.

According to the above configuration, because the space required for fixing the electronic components on the circuit board can be reduced as compared with a case in which the electronic components are fixed on the circuit board by screwing, the electronic components can be firmly mounted on the circuit board without standing in the way of making the circuit board denser.

In the above configuration, the fixing member may also be an adhesive. With this configuration, the circuit board and the mounting piece can be inexpensively and reliably fixed to the support post portion.

In the above configuration, the one electronic component may also be an inductor. Alternatively, the one electronic component may also be a transformer. The above configuration is particularly suitable for fixing a relatively large and heavy electronic component, such as an inductor or a transformer, on a circuit board. In the above configuration, the assembly member may also be a heat dissipation member. With this configuration, because the heat dissipation member can also serve as a member for fixing the circuit board and the one electronic component, an increase in the number of components can be avoided.

In the above configuration, the mounting piece or the mounting piece and the main body may also be disposed on the circuit board with a space therebetween, and another electronic component mounted on the circuit board may also be disposed in that space. With this configuration, it is possible to increase the density of the circuit device.

### ADVANTAGEOUS EFFECTS OF INVENTION

According to the circuit device disclosed in the present specification, it is possible to firmly mount electronic components on a circuit board without impeding densification of the circuit board.

### BRIEF DESCRIPTION OF DRAWINGS

FIG. 1 is a perspective view of a circuit device according to an embodiment.

FIG. 2 is a plan view of the circuit device according to the embodiment.

FIG. 3 is a front view of the circuit device according to the embodiment.

FIG. 4 is a rear view of the circuit device according to the embodiment.

FIG. 5 is a right side view of the circuit device according to the embodiment.

FIG. 6 is a cross-sectional view taken along line A-A of FIG. 2.

FIG. 7 is a cross-sectional view taken along line B-B of FIG. 2.

FIG. 8 is an exploded perspective view of the circuit device according to the embodiment.

FIG. 9 is a perspective view of a circuit board on which other electronic components are mounted in the embodiment.

FIG. 10 is a plan view of the circuit board on which other electronic components are mounted in the embodiment.

FIG. 11 is a perspective view of an inductor according to the embodiment.

FIG. 12 is a plan view of the inductor according to the embodiment.

FIG. 13 is a front view of the inductor according to the embodiment.

FIG. 14 is a right side view of the inductor according to the embodiment.

FIG. 15 is a perspective view of a coil and a magnetic core according to the embodiment.

FIG. 16 is a perspective view of a heat dissipation member according to the embodiment.

FIG. 17 is a perspective view showing how the inductor is mounted on the circuit board in the embodiment.

FIG. 18 is a perspective view showing how the heat dissipation member is assembled to the circuit board on which the inductor is mounted in the embodiment.

FIG. 19 is a partially enlarged view of the periphery of a support post portion in a circuit device according to a modification.

### DETAILED DESCRIPTION OF PREFERRED EMBODIMENTS

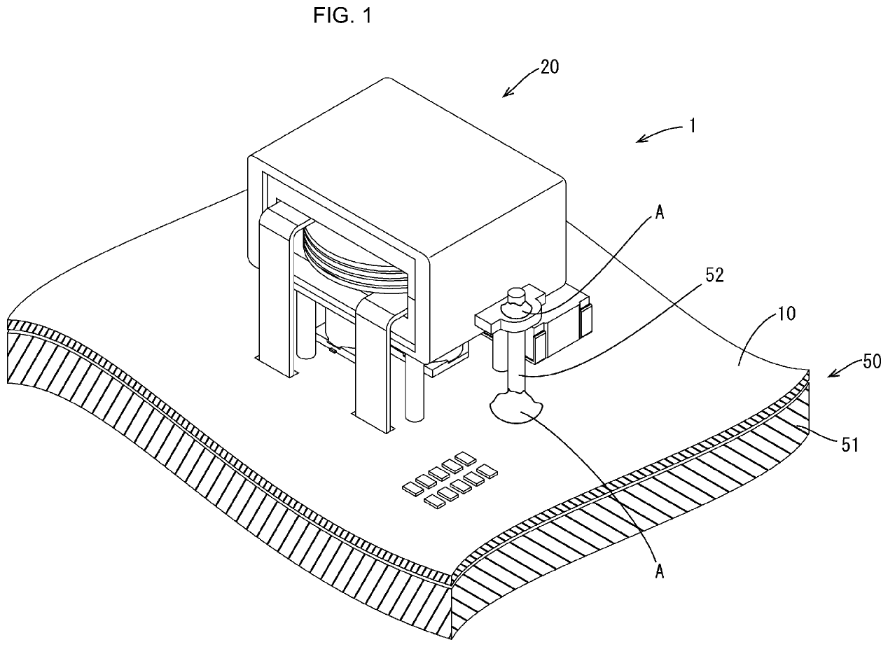

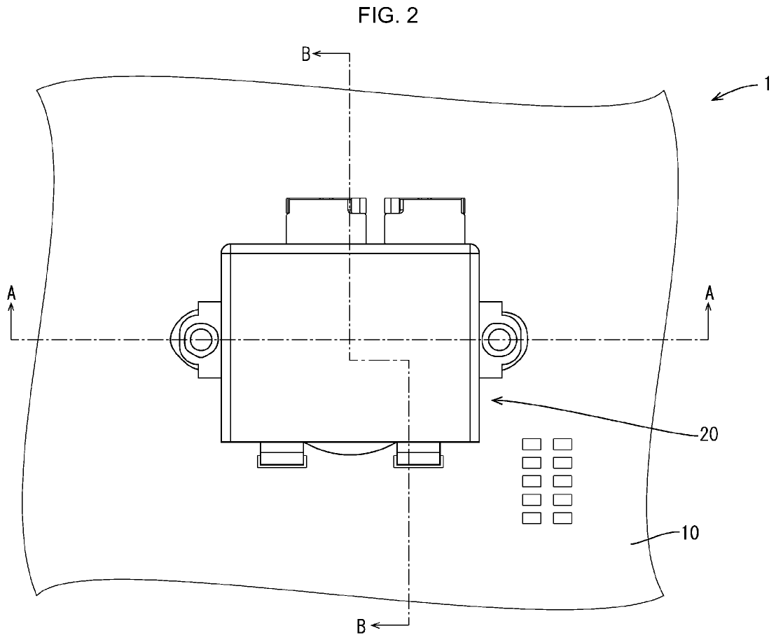

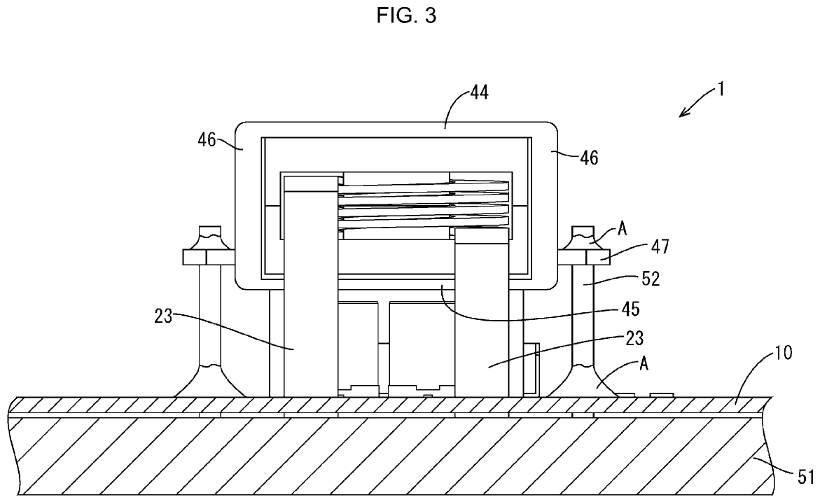

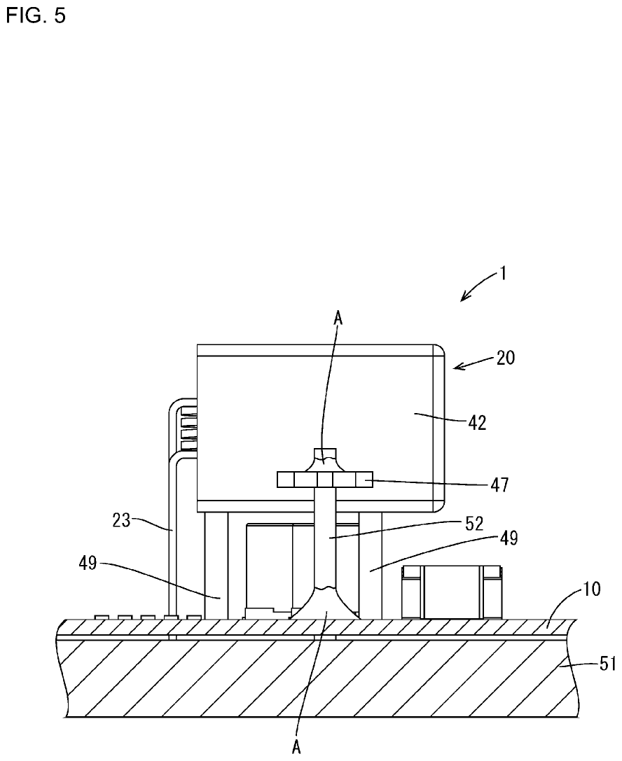

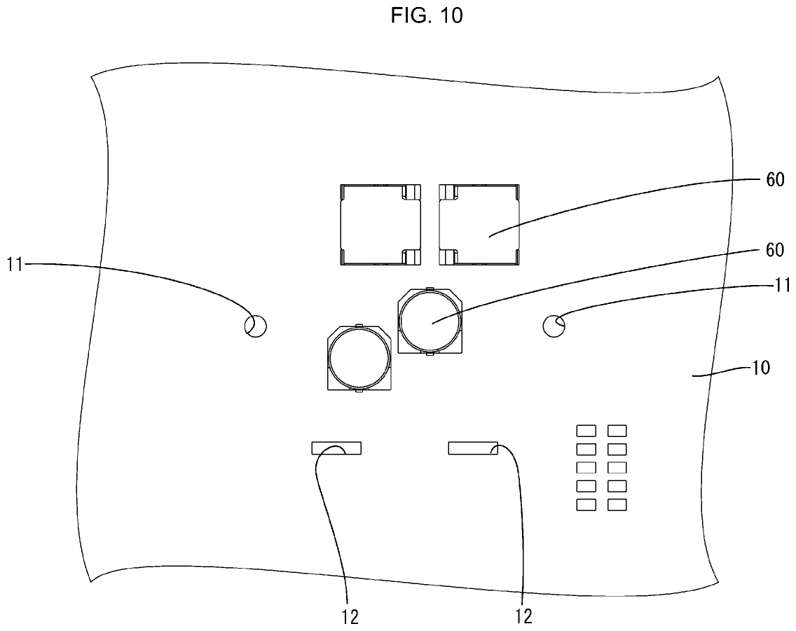

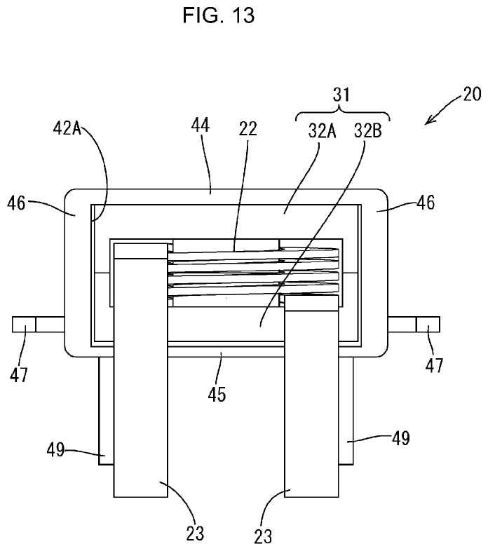

An embodiment will be described with reference to FIGS. 1 to 18. A circuit device 1 of the present embodiment is a converter device that is disposed between two power supply systems in a vehicle and converts a voltage between the power supplies

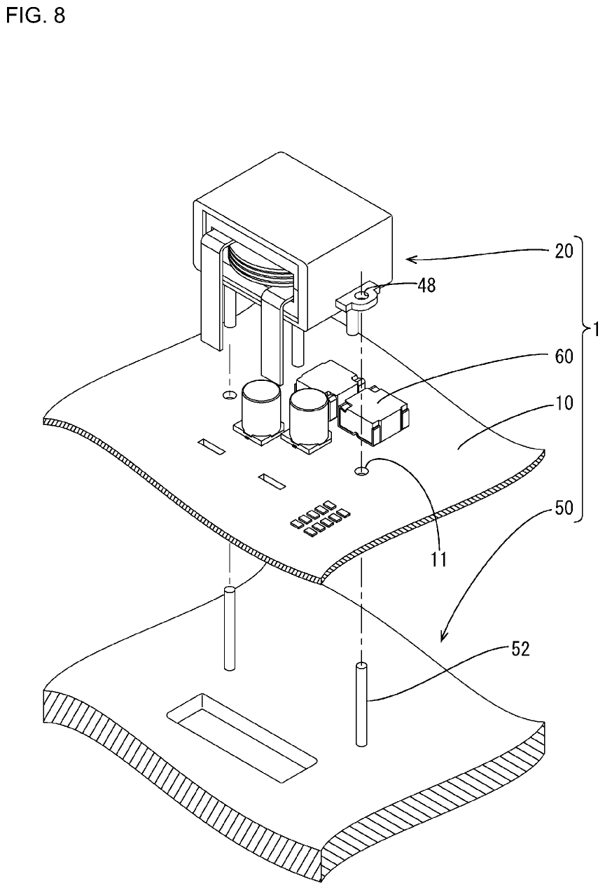

As shown in FIG. 8, the circuit device 1 includes a circuit board 10, electronic components 20 and 60 mounted on the circuit board 10, and a heat dissipation member 50 (corresponding to an assembly member) that dissipates heat generated from the circuit board 10.

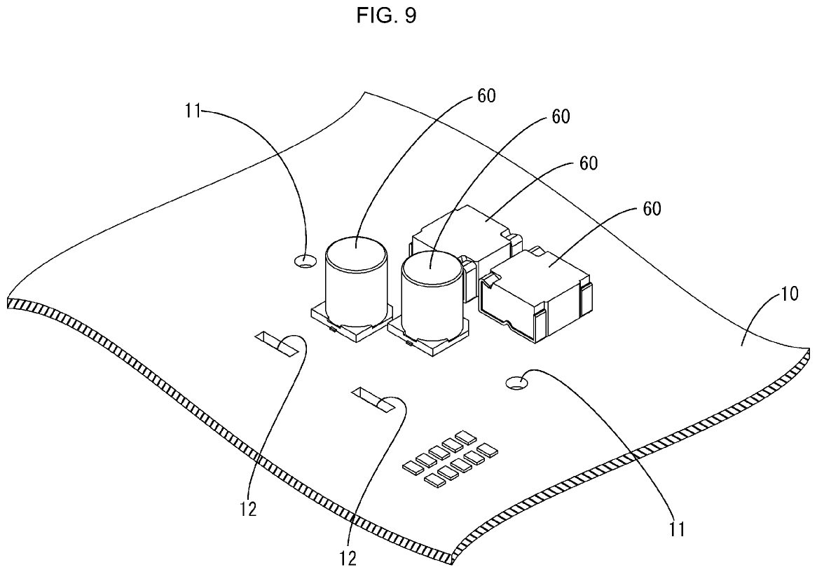

The circuit board 10 has an ordinary configuration including a conductive circuit formed by a printed wiring technique on one surface of an insulating plate made of a glass base material or a glass nonwoven fabric base material. As shown in FIG. 9, the circuit board 10 includes a pair of first support post insertion holes 11 and a pair of through holes 12.

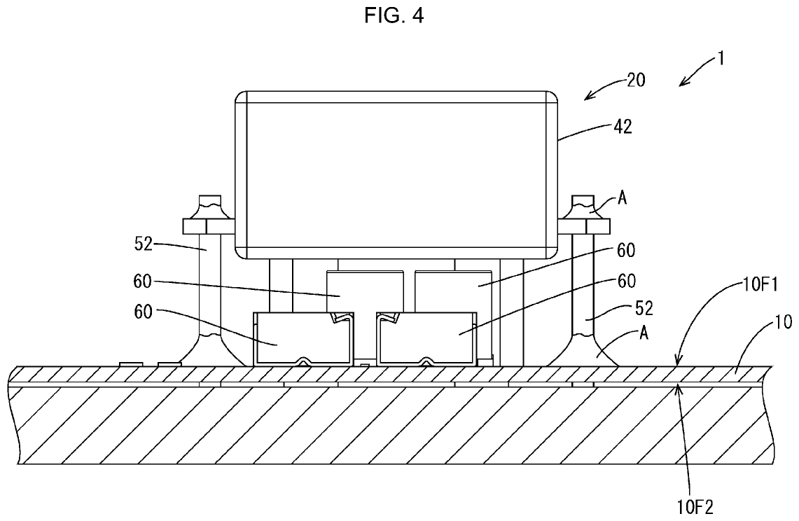

The plurality of electronic components 20 and 60 are disposed on one surface (a mounting surface 10F1: the upper surface in FIG. 4) of both front and back surfaces of the circuit board 10.

One electronic component of the plurality of electronic components 20 and 60 is the large inductor 20. The other electronic components 60 are relatively small and light components such as a field effect transistor (FET), a small inductor, a capacitor, or a resistor.

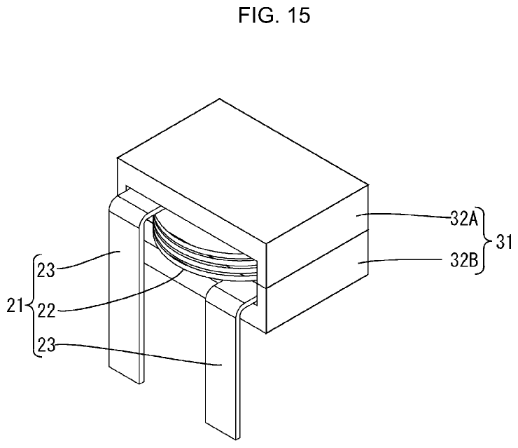

The inductor 20 includes a coil 21, a magnetic core 31, and an inductor case 41. As shown in FIG. 15, the coil 21 is an edgewise coil formed by winding a rectangular wire into an edgewise and annular shape. The coil 21 includes a winding portion 22 that is wound to form a tubular shape as a whole, and a pair of lead terminals 23 extending from the winding portion 22 in the same direction (downward in FIG. 15) along the axial direction of the winding portion 22 and connected to a conductive circuit of the circuit board 10.

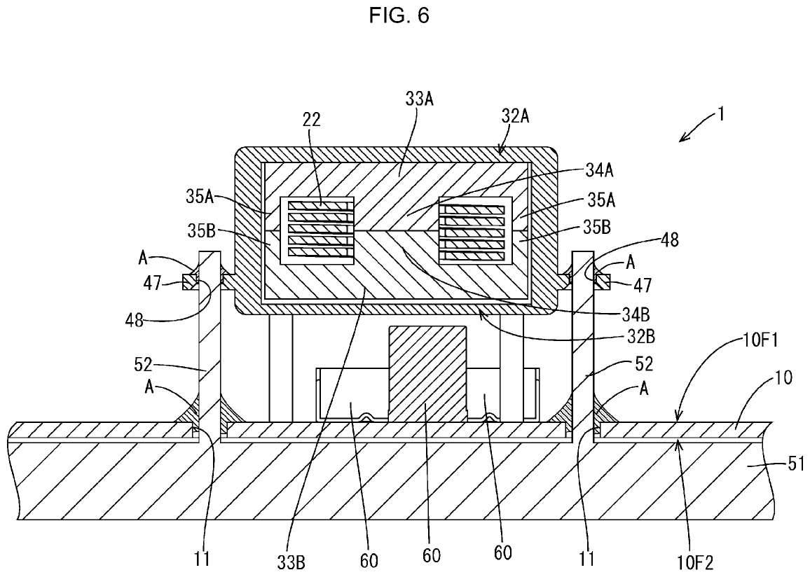

The magnetic core 31 is made of a magnetic material such as ferrite, and as shown in FIG. 15, is formed by combining a first core 32A and a second core 32B having the same shape and the same size. As shown in FIG. 6, the first core 32A includes a flat-shaped main wall portion 33A, a columnar shaft portion 34A protruding from one surface of the main wall portion 33A toward the counterpart second core 32B, and a pair of support wall portions 35A protruding in the same direction as the shaft portion 34A from a pair of opposite side edges of the main wall portion 33A. Similarly, the second core 32B also includes a main wall portion 33B, a shaft portion 34B, and a pair of support wall portions 35B. The first core 32A and the second core 32B are overlapped with each other so that the shaft portions 34A and 34B and the support wall portions 35A and 35B are butted against each other.

As shown in FIG. 6, the coil 21 is disposed between the two main wall portions 33A and 33B in a state in which the winding portion 22 is wound around the shaft portions 34A and 34B.

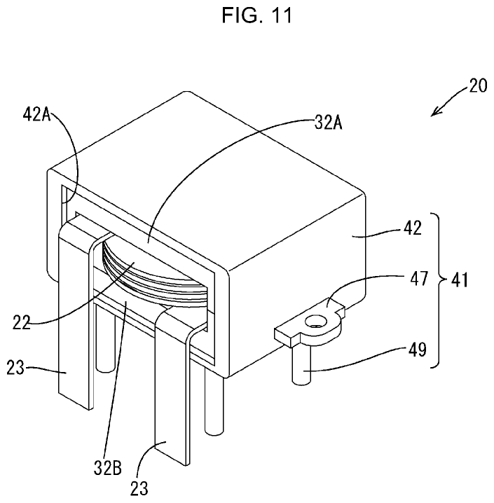

The inductor case 41 is made of synthetic resin, and as shown in FIG. 11, includes a case main body 42 (corresponding to a main body) that accommodates the magnetic core 31 and the winding portion 22 therein, a pair of mounting pieces 47 that protrude from the case main body 42, and four leg portions 49 that also protrude from the case main body 42.

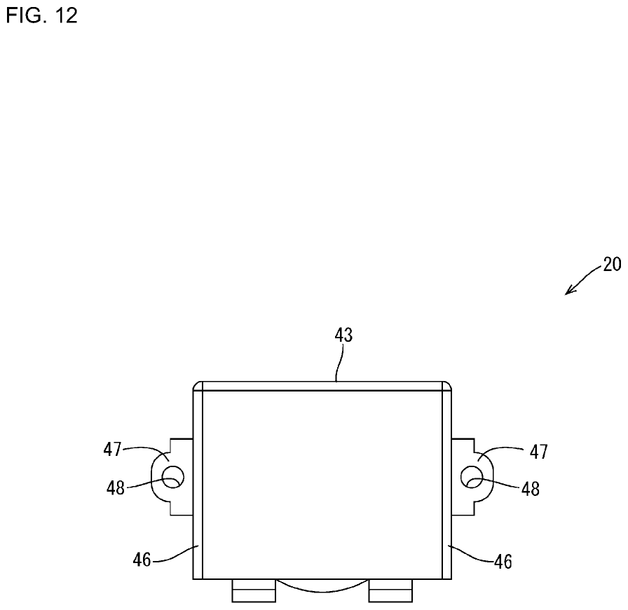

As shown in FIGS. 12, 13, and 14, the case main body 42 includes a rectangular plate-shaped back wall portion 43 and four wall portions (a top wall portion 44, a bottom wall portion 45, and a pair of side wall portions 46) respectively extending from four sides of the back wall portion 43 and surrounding the magnetic core 31 and the winding portion 22, and has an opening portion 42A on the side opposite to the back wall portion 43. The bottom wall portion 45 is a rectangular plate-shaped wall portion facing the circuit board 10. The top wall portion 44 is a rectangular plate-shaped wall portion disposed in parallel to the bottom wall portion 45 with a space therebetween. The pair of side wall portions 46 are rectangular plate-shaped wall portions that connect the bottom wall portion 45 and the top wall portion 44 to each other, and are disposed at an interval from each other.

As shown in FIG. 12, the pair of mounting pieces 47 are plate-shaped portions extending outward from the pair of side wall portions 46, respectively, and each have a second support post insertion hole 48.

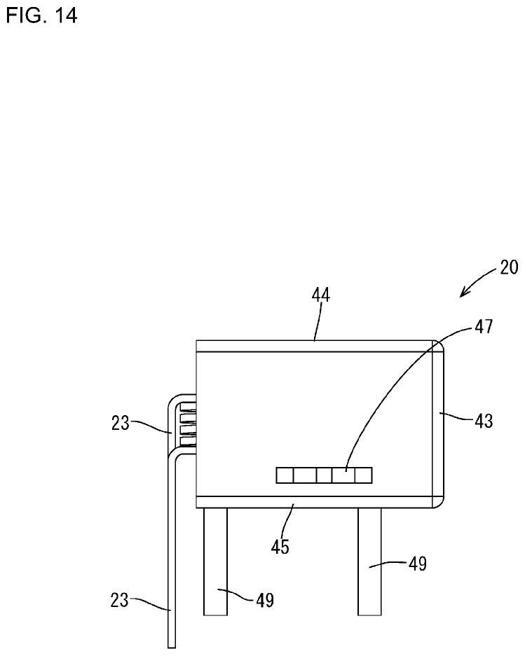

As shown in FIG. 14, the four leg portions 49 are columnar portions extending perpendicularly from the bottom wall portion 45.

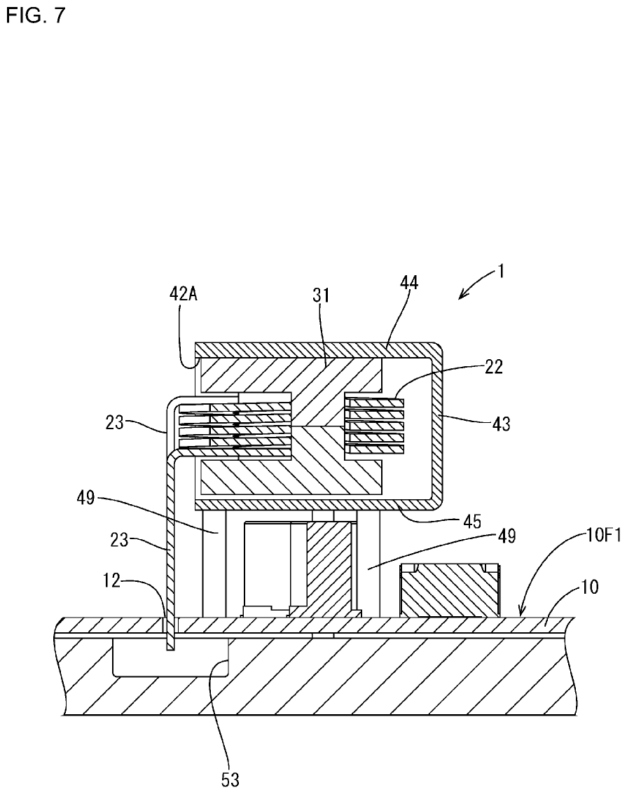

As shown in FIG. 7, the inductor case 41 is disposed on the circuit board 10 with the bottom wall portion 45 facing the circuit board 10. The four leg portions 49 are in contact with the mounting surface 10F1, and there is a relatively large space between the case main body 42 and the circuit board 10. The magnetic core 31 and the winding portion 22 are accommodated in the case main body 42, and the pair of lead terminals 23 are led out of the opening portion 42A to the outside of the main body 42, extending toward the circuit board 10. The distal ends of the pair of lead terminals 23 are respectively inserted into the pair of through holes 12 of the circuit board 10 and soldered, so that the coil 21 is electrically connected to the conductive circuit of the circuit board 10.

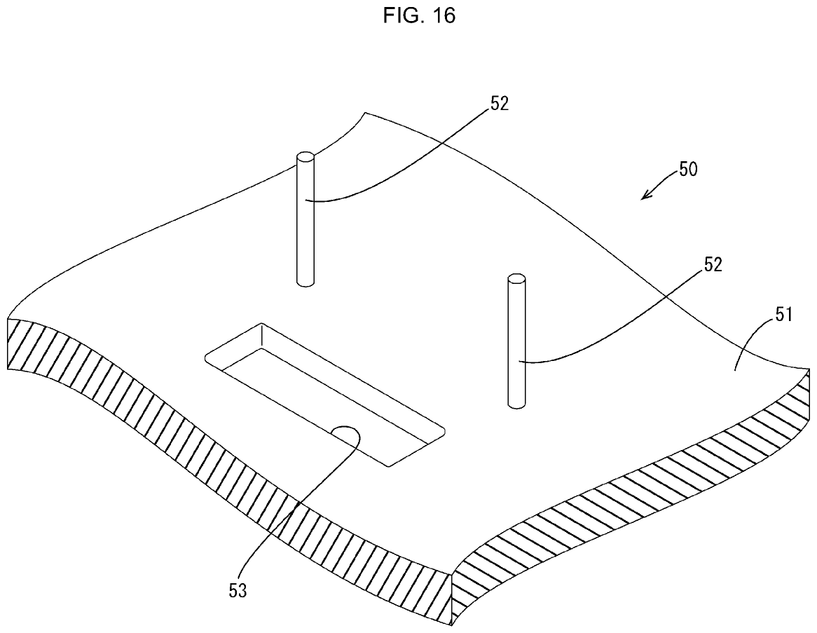

The heat dissipation member 50 is a member made of metal such as aluminum or an aluminum alloy having high thermal conductivity, and as shown in FIG. 16, includes a main plate portion 51 (corresponding to a base portion) and a pair of support post portions 52 protruding from the main plate portion 51. The main plate portion 51 is a flat plate-shaped portion that is slightly larger than the circuit board 10, and as shown in FIG. 7, has a relief recessed portion 53 that can receive the distal ends of the lead terminals 23. The pair of support post portions 52 are round bar-shaped portions that protrude perpendicularly from one surface (the upper surface in FIG. 6) of the main plate portion 51 that faces the circuit board 10 to the main plate portion 51. The pair of support post portions 52 are formed integrally with the main plate portion 51 by, for example, die casting.

The main plate portion 51 is disposed along the other surface (a heat dissipation surface 10F2: the lower surface in FIG. 6) of the front and back surfaces of the circuit board 10, and is fixed to the circuit board 10 by screwing. As shown in FIG. 6, one of the pair of support post portions 52 is inserted through one first support post insertion hole 11 and one second support post insertion hole 48. In the circuit board 10, the circumferential edge portion of the one first support post insertion hole 11 and the one support post portion 52 are bonded by an adhesive A (corresponding to a fixing member), and in one mounting piece 47, the circumferential edge portion of the second support post insertion hole 48 and the one support post portion 52 are bonded by the adhesive A. Similarly, the other support post portion 52 is inserted into the other first support post insertion hole 11 and the other second support post insertion hole 48, and is bonded to the circuit board 10 and the other mounting piece 47 by the adhesive A.

In the space between the case main body 42 and the circuit board 10, as shown in FIG. 4, other electronic components 60 mounted on the circuit board 10 are disposed between the two support post portions 52.

An example of a process of manufacturing the circuit device 1 by assembling the circuit board 10, the inductor 20, and the heat dissipation member 50 will be described below.

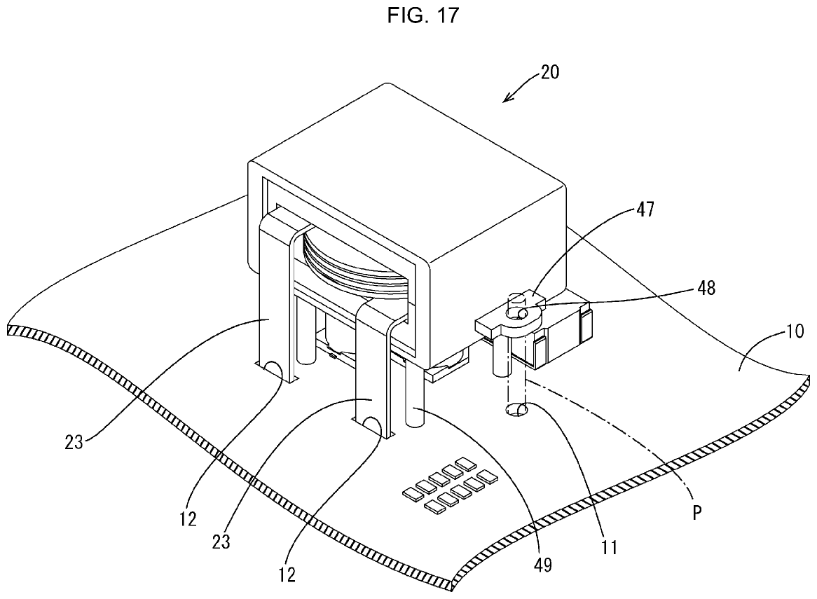

First, as shown in FIG. 17, two positioning pins P for positioning the inductor 20 are erected from a soldering jig on the circuit board 10 on which other electronic components 60 are mounted. The two positioning pins P are columnar members each having an outer diameter substantially equal to that of the support post portion 52, and are vertically erected with respect to the circuit board 10 in a state in which the two positioning pins P are respectively inserted into the pair of first support post insertion holes 11 at one end.

Next, the inductor 20 is mounted on the circuit board 10. By inserting the two positioning pins P into the two second support post insertion holes 48, respectively, the four leg portions 49 are bought into contact with the mounting surface 10F1 of the circuit board 10 while positioning the inductor 20. The two lead terminals 23 are inserted into the two through holes 12, respectively, and connected by soldering.

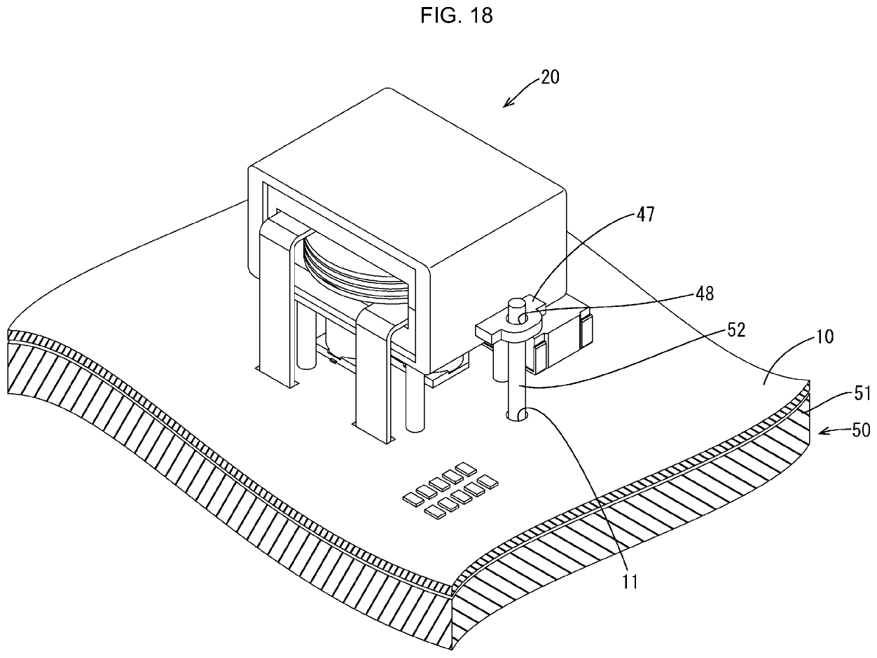

Next, the positioning pins P are removed from the circuit board 10, and the circuit board 10 is assembled to the heat dissipation member 50. As shown in FIG. 18, the two support post portions 52 are respectively inserted into the two first support post insertion holes 11 and the two second support post insertion holes 48 from the heat dissipation surface side 10F2, and the circuit board 10 is overlaid on the main plate portion 51. Then, the circuit board 10 and the main plate portion 51 are fixed to each other by screws (not shown).

Next, as shown in FIG. 1, the adhesive A is applied around the two support post portions 52 on the mounting surface 10F1 of the circuit board 10. Further, the adhesive A is applied around the two support post portions 52 in the mounting pieces 47. By curing the adhesive A, the support post portions 52 and the circuit board 10, and the support post portions 52 and the mounting pieces 47 are fixed to each other.

As described above, according to the present embodiment, the circuit device 1 includes the circuit board 10, the inductor 20 mounted on the circuit board 10, and the heat dissipation member 50 to which the circuit board 10 and the inductor 20 are assembled. The inductor 20 includes the case main body 42, and the mounting pieces 47 extending from the case main body 42 in parallel with the circuit board 10. The heat dissipation member 50 includes the main plate portion 51 disposed along the circuit board 10, and the support post portions 52 extending from the main plate portion 51 and penetrating the circuit board 10 and the mounting pieces 47. The circuit board 10 and the mounting pieces 47 are fixed to the support post portions 52 by the adhesive A.

According to the above configuration, because the space required for fixing the inductor 20 on the circuit board 10 can be reduced as compared with the case in which the inductor 20 is fixed on the circuit board 10 by screwing, the inductor 20 can be firmly mounted on the circuit board 10 without impeding the high density of the circuit board 10. This configuration is particularly suitable for fixing a relatively large and heavy electronic component, such as the inductor 20, to the circuit board 10.

Also, the circuit board 10 and the support post portions 52, and the mounting pieces 47 and the support post portions 52 are fixed by the adhesive A. With this configuration, screwing of the circuit board 10 can be omitted, and the circuit board 10 and the mounting pieces 47 can be reliably fixed to the support post portions 52 at low cost.

The circuit board 10 and the inductor 20 are fixed to each other by the heat dissipation member 50. With this configuration, because the heat dissipation member 50 can also serve as a member for fixing the circuit board 10 and the inductor 20, an increase in the number of components can be avoided.

The case main body 42 of the inductor 20 is disposed with the space between the case main body 42 and the circuit board 10, and other electronic components 60 mounted on the circuit board 10 are disposed in that space. With this configuration, it is possible to increase the density of the circuit device 1.

### Other Embodiments

The technology disclosed in the present specification is not limited to the embodiment described above and illustrated in the drawings, and includes, for example, the following various aspects.

In the above embodiment, the circuit board 10 and the support post portions 52, and the circuit board 10 and the mounting pieces 47 are fixed by the adhesive A. However, for example, the mounting pieces and the support post portions may also be fixed by screwing nuts to the support post portions each having a screw thread on their outer circumferential surface.

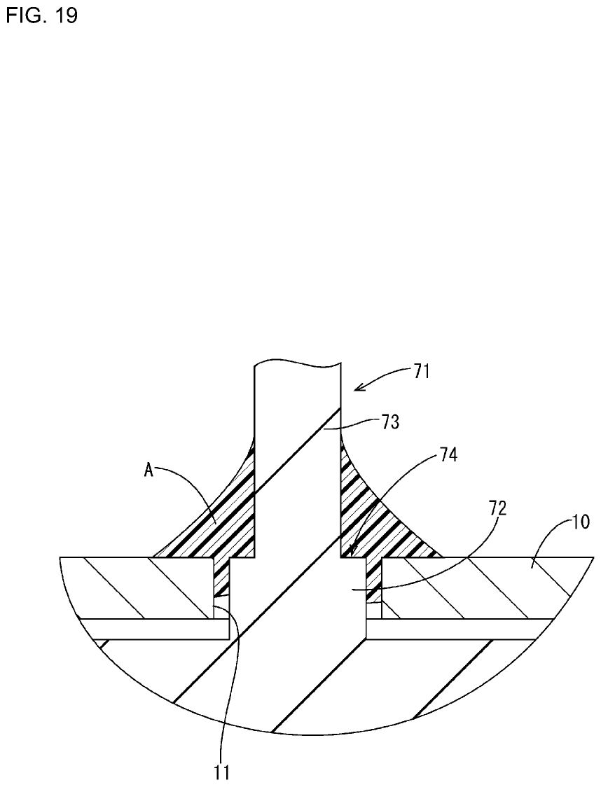

As shown in FIG. 19, for example, a root portion of each support post portion 71 accommodated in the first support post insertion hole 11 may also be an enlarged diameter portion 72 having a larger diameter than the other portion (a reduced diameter portion 73). With this configuration, because the adhesive A also adheres to a step surface 74 between the reduced diameter portion 73 and the enlarged diameter portion 72, the adhesion between the circuit board 10 and the support post portion 71 can be further strengthened.

In the above embodiment, the support post portions 52 are formed integrally with the main plate portion 51. However, the support post portions may also be formed separately from the base portion, and may also be fixed to the base portion by bonding, welding, screwing, or the like.

The fixing member may also not be a heat dissipation member, but is preferably a member made of a material having a certain degree of strength, such as metal.

In the above embodiment, the inductor 20 is disposed with a space between the inductor 20 and the circuit board 10, and other electronic components 60 mounted on the circuit board 10 are disposed in that space. However, the electronic components may also be disposed in contact with the circuit board.

In the above embodiment, the one electronic component is a large inductor, but the one electronic component may also be a transformer.

1. A circuit device, comprising:
a circuit board;
one electronic component mounted on the circuit board; and
an assembly member to which the circuit board and the one electronic component are assembled, wherein
the one electronic component includes a main body and a mounting piece extending from the main body in parallel with the circuit board,
the assembly member includes a base portion disposed along the circuit board, and a support post portion extending from the base portion and penetrating the circuit board and the mounting piece, and
the circuit board is fixed to the support post portion, and the mounting piece is fixed to the support post portion, by a fixing member.

2. The circuit device according to claim 1, wherein the fixing member is an adhesive.

3. The circuit device according to claim 1, wherein the one electronic component is an inductor.

4. The circuit device according to claim 1, wherein the one electronic component is a transformer.

5. The circuit device according to claim 1, wherein the assembly member is a heat dissipation member.

6. The circuit device according to claim 1, wherein the mounting piece or the mounting piece and the main body are disposed on the circuit board with a space therebetween, and another electronic component mounted on the circuit board is disposed in that space.
